(19) United States
(12) Patent Application Publication
(10) Pub. No.: US 2026/0068692 A1
(43) Pub. Date: Mar. 5, 2026

(54) SEMICONDUCTOR PACKAGES WITH WETTABLE FLANKS AND RELATED METHODS

(71) Applicant: SEMICONDUCTOR COMPONENTS INDUSTRIES, LLC, Scottsdale, AZ (US)

(72) Inventors: Hui Min LER, Seremban (MY); Wing Heng WONG, Seramban (MY)

(73) Assignee: SEMICONDUCTOR COMPONENTS INDUSTRIES, LLC, Scottsdale, AZ (US)

(21) Appl. No.: 18/817,746

(22) Filed: Aug. 28, 2024

(51) Int. Cl. H01L 23/495; H01L 25/065

(52) U.S. Cl. CPC H01L 23/49548

(57) ABSTRACT

Implementations of a substrate may include a first side coupled with a first plurality of leads, the first side including a first set of spaced apart through holes therein; and a second side coupled with a second plurality of leads, the second side including a second set of spaced apart through holes therein. The first side may oppose the second side where a portion of a first set of edges of the first set of spaced apart through holes form a first set of wettable flanks for the first plurality of leads; and a portion of a second set of edges of the second set of spaced apart through holes form a second set of wettable flanks for the second plurality of leads.

### BACKGROUND

### 1. Technical Field

Aspects of this document relate generally to semiconductor packages. More specific implementations involve semiconductor packages that employ leadframes.

### 2. Background

Various semiconductor package designs have been devised that permit for routing of electrical signals from a semiconductor die to a circuit board or motherboard to which the semiconductor die is attached. Other semiconductor packages provide shock or vibration protection to a semiconductor die including mechanical support.

### SUMMARY

Implementations of a substrate may include a first side coupled with a first plurality of leads, the first side including a first set of spaced apart through holes therein; and a second side coupled with a second plurality of leads, the second side including a second set of spaced apart through holes therein. The first side may oppose the second side where a portion of a first set of edges of the first set of spaced apart through holes form a first set of wettable flanks for the first plurality of leads; and a portion of a second set of edges of the second set of spaced apart through holes form a second set of wettable flanks for the second plurality of leads.

Implementations of a substrate may include one, all, or any of the following:

The substrate may include a set of die flags.

The substrate may include a set of tie bars.

The first set of wettable flanks and the second set of wettable flanks may be configured to extend beyond a surface of an electrically insulating material when an electrically insulating material may be coupled over the substrate.

Implementations of a semiconductor package may include a substrate which may include a first side coupled with a first plurality of leads, the first side including a first set of through holes therein; and a second side coupled with a second plurality of leads, the second side including a second set of through holes therein. The package may include one or more semiconductor die coupled to the substrate; and an electrically insulating material coupled over the one or more semiconductor die and coupled to the substrate. The first set of edges of the first set of spaced apart through holes may extend from the electrically insulating material. The second set of edges of the second set of spaced apart through holes may extend from the electrically insulating material.

Implementations of a semiconductor package may include one, all, or any of the following:

The first set of edges may form a first set of wettable flanks for the first plurality of leads.

The second set of edges may form a second set of wettable flanks for the second plurality of leads.

Remaining portions of the first side may each include two reentrant openings forming a T-shape.

Remaining portions of the second side may each include two reentrant openings forming a T-shape.

Each edge of the first set of edges may include a straight line.

Each edge of the second set of edges may include a straight line.

An edge of the first set of edges may include a reentrant angle.

An edge of the second set of edges may include a reentrant angle.

An edge of the first set of edges may include a reentrant opening.

An edge of the second set of edges may include a reentrant opening.

Flanks of the first plurality of leads and the second plurality of leads may be straight cut.

Flanks of the first plurality of leads and the second plurality of leads may be flared.

Flanks of the first plurality of leads and the second plurality of leads may be tapered.

Implementations of a method of forming a semiconductor package may include providing a substrate which may include a first side coupled with a first plurality of leads, the first side including a first set of through holes therein; and a second side coupled with a second plurality of leads, the second side including a second set of through holes therein. The method may include coupling one or more semiconductor die to the substrate; applying an electrically insulating material over the one or more semiconductor die and to the substate; cutting the first plurality of leads at each through hole of the first set of through holes; and cutting the second plurality of leads at each through hole of the second set of through holes.

Implementations of a method of forming a semiconductor package may include one, all, or any of the following:

The method may include preventing electrically insulating material bleed using two reentrant openings in each lead of the first plurality of leads and two reentrant openings in each lead of the second plurality of leads.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a detail view of a side of a substrate/leadframe showing a set of spaced apart through holes therein;

FIG. 2 is a detail view of a through hole during a molding operation showing reduction in mold bleed out;

FIG. 3 is a top view of a substrate/leadframe following die bonding, clip bonding, and wire bonding;

FIG. 4 is a top view of the substrate/leadframe of FIG. 3 following application of a mold compound thereto;

FIG. 5 is a top view of the substrate/leadframe of FIG. 4 following an electroplating operation;

FIG. 6 is a top view of a first implementation of a semiconductor package;

FIG. 7 is a side view of the semiconductor package implementation of FIG. 6;

FIG. 8 is a top and a side view of a second implementation of a semiconductor package;

FIG. 9 is a top and a side view of a third implementation of a semiconductor package;

FIG. 10 is a top and a side view of a fourth implementation of a semiconductor package; and

FIG. 11 is a flow diagram of an implementation of a process of forming a semiconductor package.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

Various semiconductor packages include one or more leads designed to allow for mechanical and/or electrical bonding/coupling with a circuit board/motherboard to which the semiconductor package is attached. While the term “lead” and “leads” are used herein, these are non-limiting examples of electrical connectors, so in the various implementations disclosed herein, other electrical connector types could be employed including, by non-limiting examples, pads, pins, lands, or other electrical connector types. Furthermore, the leads disclosed herein may be made of any material or combination of materials of electrically conductive materials disclosed herein. As part of the bonding process, automated inspection tools are employed to assess whether and what quality of bond exists between the leads and the circuit board/motherboard. The ability for solder used in bonding the leads to wick, wet, or otherwise climb the flanks of the leads during the bonding process creates a much more visible indication of the quality of the bond. Also, the height of a solder fillet formed between the flank of the leads and the circuit board/motherboard pad has been observed to increase the mechanical strength of the bond and can increase the reliability of the bond as well.

At least part of the challenge with getting solder to wet or wick up the side of a flank of a lead is because the material of the bulk material of the lead itself is often not as solder wettable as the material of electroplated layers applied over the bulk material of the lead during manufacture. In semiconductor package manufacturing operations where substrates, some in the form of leadframes, are employed, the flank of the lead is often not exposed until a final or close to final cutting/singulation step which severs electrical connection between the one or more leads and any remaining structure of the leadframe. In this situation, while electroless deposition can be employed to apply a solder wettable material to the flanks of the leads, the total thickness (1-2 microns) of the solder wettable material that can be formed in an electroless deposition process is less than what is needed to create an optimal wettable flank. Since the total thickness of the electroless process is too low, total coverage (100%) of the flank or substantial coverage (90%+) coverage are not possible to achieve. Finally, to protect the electrolessly deposited layer from humidity that reduces solder wettability, the resulting semiconductor packages need to be dry packed before shipping to the customer, which adds a process step with corresponding additional expense to the process.

While in this document the use of the term “leadframe” is employed, the principles disclosed herein may be applied to a wide variety of substrate types which can be formed to create electrically conducting pads, such as, by non-limiting example, direct bonded copper substrates, alumina substrates, insulated metal substrates, laminated substrates, printed circuit boards, metal substrates, metal-containing substrates, or any other substrate type which includes electrically conducting pathways formed therein or thereon. Similarly, the “lead” or “leads” discussed in this document, these are merely examples of a type of an electrically conducting pad that could be utilized in various substrate implementations to form electrically conductive pathways between a semiconductor die and a circuit board/motherboard to which the semiconductor package is coupled.

Referring to FIG. 1, a detail view of an edge 4 of a leadframe/substrate 2 over which mold compound 6 has been applied is illustrated. This leadframe 2 may be for a single semiconductor package (1-up), two semiconductor packages (2-up), or any additional number of semiconductor packages (3-up or higher). The leadframe 2 may in the form of a strip which contains multiple semiconductor packages in a line or in the form of a panel which contains multiple semiconductor packages arranged in a grid. Furthermore, while a single semiconductor die may be included in the resulting semiconductor package, the leadframe may be adapted to allow for bonding of two or more die in each semiconductor package whether in stacked form, side-by-side, interlocking, die bonded, or overlapping configuration. A wide variety of semiconductor die may be employed in various implementations including, by non-limiting example, diodes, metal oxide semiconductor field effect transistors (MOSFETs), insulated gate bipolar transistors (IGBTs), high electron mobility transistors (HEMTs), transistors, thyristors, rectifiers, power devices, or any other semiconductor device type. The semiconductor die may also be made of various semiconductor substrate materials, including, by non-limiting example, silicon, silicon carbide, silicon-on-insulator, gallium arsenide, ruby, sapphire, or any other semiconductor substrate type. A wide variety of bonding techniques may also be employed to attach the die to the leadframe, including, by non-limiting example, sintering, bonding, die attach film, soldering, or any other bonding process or method that can form a mechanical and/or electrical bond between the material of the semiconductor die and the material of the leadframe.

As illustrated in FIG. 1, the edge 4 of the leadframe/substrate 2 includes several spaced apart through holes (spaced openings) 8, 10, 12, 14. These spaced apart through holes 8, 10, 12, 14 extend completely through a thickness of the leadframe 2. Adjacent to/on one side of the spaced apart through holes 8, 10, 12, 14 is a set of additional openings 16 that help define the internal structure of the leads included in the semiconductor package. Edge 4 is the outer edge of the material of the leadframe 2.

Spaced apart through hole 8 is formed of two straight edges 18 joined by two pairs of straight edges oriented at an obtuse angle 20, 22 to one another. As illustrated in FIG. 1, obtuse angle 22 is a reentrant angle because it extends into the material of the leadframe toward the center of the leadframe (located in the direction of the bottom of the page). The additional openings 16 are formed using acute angles 24 which are also reentrant angles because they extend into the material of each lead 26. In particular implementations disclosed herein, the acute angles 24 form reentrant openings, which are, as used herein, openings that begin on one side of the lead, extend into the material of the lead, and then exit on the same side of the lead.

As illustrated in FIG. 1, spaced apart through hole 10 has the shape of rectangle with rounded corners. While the use of rounded corners is illustrated in FIG. 1, square corners could also be utilized in various implementations, and, in some implementations, the rectangular shape may be a square. Spaced apart through hole 12 has a similar rectangular shape with rounded corners as spaced apart through hole 10, except a reentrant opening 28 in the form of an arc is included. The use of the reentrant opening 28 may assist with solder wetting by forming a channel in the flank of the lead 26 that facilitates flow of solder under surface tension force into the channel and which increases the overall surface area of the flank.

FIG. 1 also illustrates spaced apart through hole 14 that has the form of a trapezoid with rounded corners. While rounded corners are illustrated in FIG. 1, the trapezoid may have sharp angled corners in other implementations. While particular shapes of the spaced apart through holes 8, 10, 12, 14 are illustrated in FIG. 1, other shapes may be employed, including, by non-limiting example, elliptical shapes, circular shapes, triangular shapes, polygonal shapes, or any closed shape that is substantially symmetric about a center line of the leads26. Also, while the use of spaced apart through holes is illustrated in FIG. 1, a similar effect could be created where the holes are not closed but extend over the edge 4 of the leadframe, forming reentrant openings. In such implementations, processing may be more difficult/challenging due to the sharp exposed edges of the reentrant openings and/or the reduction in mechanical strength of the leadframe due to the openings in the edge 4. Finally, a combination of reentrant openings and spaced apart through holes may employed in various leadframe implementations.

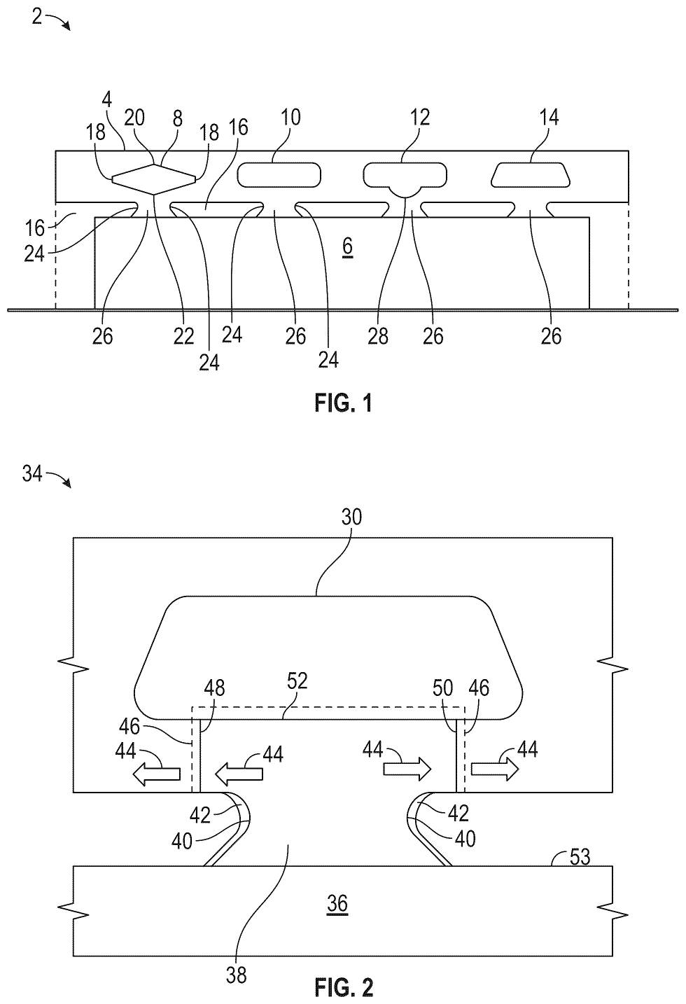

Referring to FIG. 2, a detail view of an implementation of a spaced apart through hole 30 is illustrated in place in an edge 32 of leadframe/substrate 34. The shape of this spaced apart through hole 30 is a trapezoid with rounded corners. An electrically insulative material (in this case, a mold compound) 36 is illustrated applied over lead 38. The reentrant openings 40 that extend into the material of the lead 38 have the effect of acting as a reservoir that can take up a certain amount 42 of bleeding out mold compound along the sides of the lead 38 during the molding process, thereby preventing it from moving in the direction of arrows 44 toward the flanks of the leads. In this way, the reentrant openings 40 form a “bottle neck” shape that serves to bottle up/limit mold bleed out onto the lead. FIG. 2 also shows the locations 46 where the end of the lead 38 is cut via punching, stamping, etc. away from the remaining material of the edge of the hole 30. The resulting end of the lead 38 takes the outline of the dotted line region in FIG. 2, which together form a set of edges 52 that collectively form the flank of the lead 38.

As will be described hereafter, edge 52 has an electroplated layer formed thereon (not shown in FIG. 2) which contains a solder wettable material. Since edge 48 and 50 are cut after the formation of the electroplated layer, they do not have electroplated material on them but are just formed of the exposed material of the leadframe itself. Thus, the edges 48 and 50 may be solder wettable, but not as solder wettable as edge 52 in various implementations. However, because the edges 48 and 50 are cut from exposed material of the lead itself, no burr in the face of the mold compound may be created as a result which can further hinder wettability of the flank. Because the edge 52 is located substantially parallel with the edge 53 of the mold compound 36 (the package outline) and substantially at 90 degrees to a longest length of the lead 38, the most wettable edge 52 of the flank is positioned to be most visible to optical inspection equipment designed to assess the presence of solder wetting and the strength of the bond between the lead and a circuit board/motherboard.

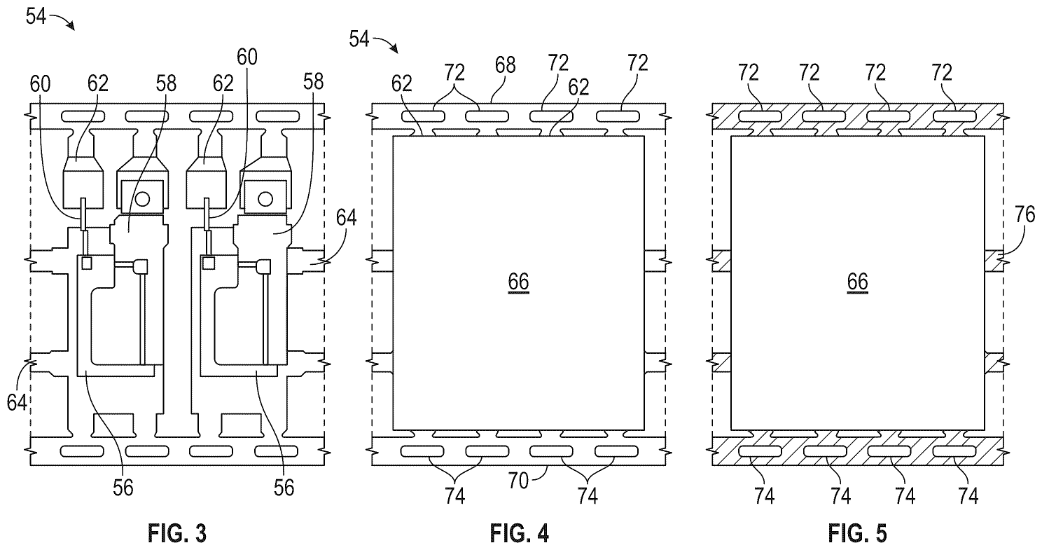

The semiconductor packages disclosed herein may be manufactured using various methods of forming a semiconductor package. Referring to FIG. 3, an implementation of a leadframe/substrate 54 is illustrated following bonding of two semiconductor die 56 thereto. Electrical connectors (in this case clips 58) have also been placed and bonded over each of the two semiconductor die 56 and electrical connectors (in this case wirebonds 60) have also been formed between the two semiconductor die 56 and leads 62 and the clips 58. Also visible in FIG. 3 are tie bars 64 which, while they will be visible through the material of the electrically insulative material/mold compound in the finished semiconductor package, are not used for bonding to the circuit board/motherboard.

FIG. 4 illustrates the leadframe/substrate 54 of FIG. 3 following application of electrically insulative material (in this case mold compound 66) over the semiconductor die 56, clips 58, wirebonds 60, and tie bars 64 leaving the ends of the leads 62 exposed along with the edges 68, 70 (first edge 68, second edge 70) of the leadframe 54. Also exposed is a first set of through holes 72 in the first edge 68 and a second set of through holes 74 in the second edge 70. FIG. 5 illustrates the leadframe/substrate 54 of FIG. 4 following formation of an electroplated layer 76 on the exposed surfaces of the leadframe 54 including the edges of the first set of through holes 72 and second set of through holes 74. As previously discussed, the material of the electroplated layer 76 is more solder wettable than the material of the leadframe 54 itself. By non-limiting example, the material of the electroplated layer may be, by non-limiting example, tin, silver, gold, nickel, copper, alloys of tin, alloys of silver, alloys of gold, alloys of nickel, alloys of copper, any combination thereof, or any other alloy or layers of various materials more wettable to solder than the material of the leadframe 54 itself. The substrate, leadframe and/or leads in this implementation and in the others disclosed herein may be made of, by non-limiting example, copper, aluminum, nickel, silver, alloys of copper, alloys of aluminum, alloys of nickel, alloys of silver, any combination thereof or any other material disclosed herein capable of provide electrical connections.

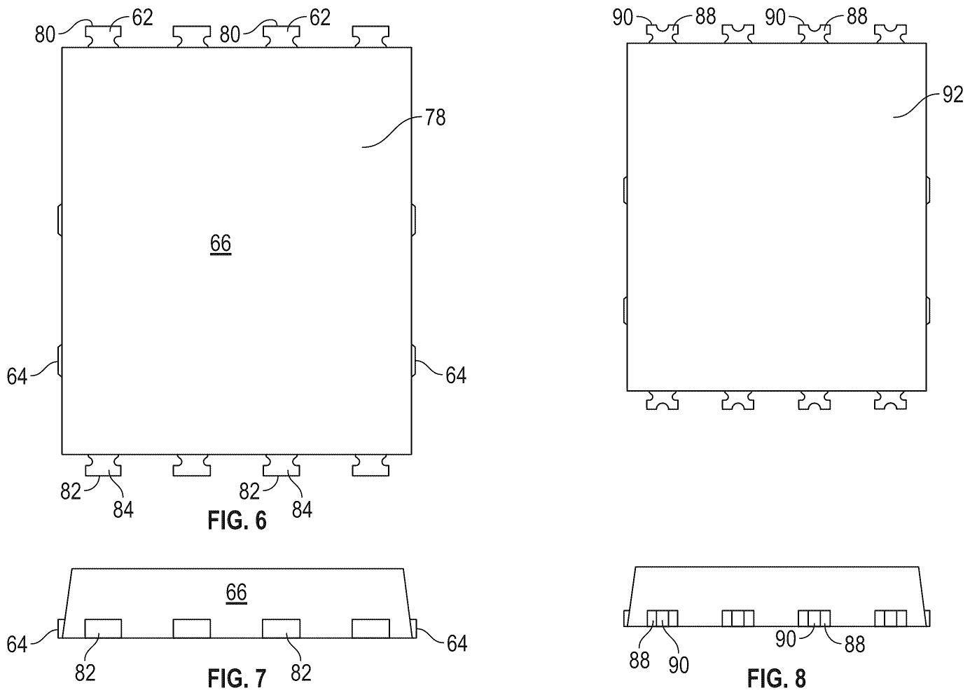

While in the method implementation illustrated in FIG. 5, the exposed portions of the leadframe 54 were electroplated after the mold compound 66 was applied, in other method implementations, the leadframe 54 may electroplated prior to bonding of the semiconductor die 56 thereto. In such a method implementation, following application of the mold compound, the leads would then immediately proceed to cutting. In the method implementation illustrated in FIG. 6, the leads 62 are shown after cutting takes place, separating the semiconductor package 78 from the edges 68, 70 of the leadframe 54. Because the interior edges of the first set of through holes 72 and of the second set of through holes 74 was electroplated, a first set of wettable flanks 80 for leads 62 and a second set of wettable flanks 82 for leads 84 are now exposed and ready for bonding as illustrated in the side view of FIG. 7. FIG. 7 also illustrates how the tie bars 64 extend from the mold compound 66 but are not configured for use as leads.

As illustrated in FIG. 1, a wide variety of shapes for the through holes in the edges of the leadframe may be employed, each of which results in a different shape for the flank of the leads. Different combinations of shapes for the through holes for different leads could also be employed in a leadframe for the same semiconductor package. Referring to FIG. 8, a top view and side view of leads 88 and flanks 90 for a semiconductor package 92 that are cut from through holes with the same shape as spaced apart through hole 12 illustrated in FIG. 1. As illustrated, the reentrant opening 28 of the through hole 12 results in a set of flanks that have channels/grooves therein that are coated with a solder wettable material and so offer correspondingly greater surface area.

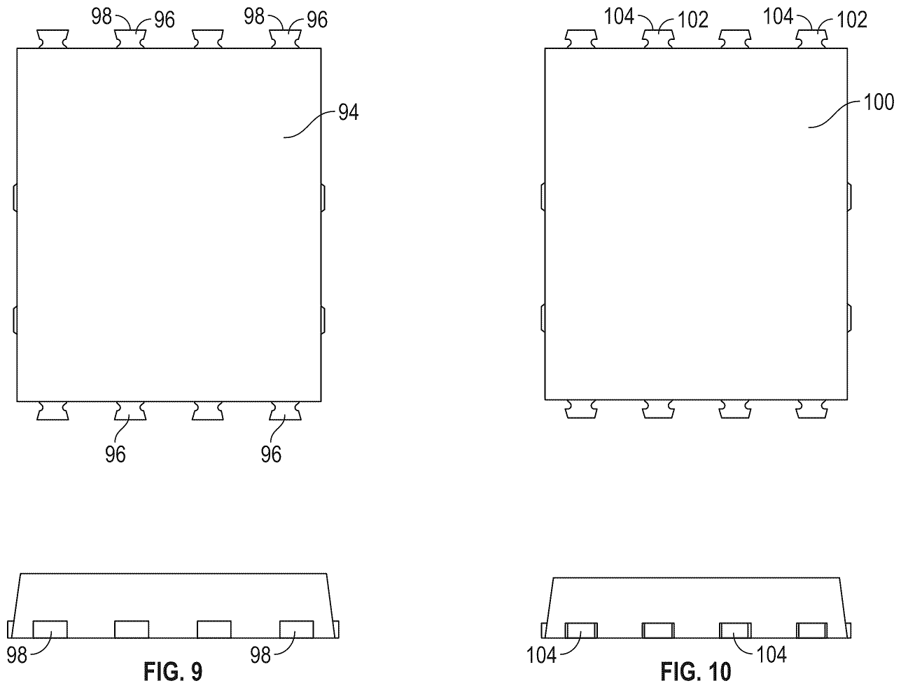

Referring to FIG. 9, another semiconductor package implementation 94 is illustrated following cutting of the leads 96 where the through holes had the appearance of spaced apart through hole 14 from FIG. 1. In this implementation, however, the cuts were not made substantially parallel with a longest length of the leads 96, but at an angle away from the center of the leads to form flared leads. The use of the angled cuts to form flared leads results in an increased size of the flanks 98 that include solder wettable electroplated layer thereon. For comparison, FIG. 10 illustrates a semiconductor package implementation 100 where the leads are cut from through holes with the identical shape of the leads 96 of FIG. 9, but are now cut at an angle toward the center of the leads 102 to produce tapered leads. The resulting flanks 104 are now narrower/smaller than in the case of the straight cut leads of FIG. 8 and the flared leads of FIG. 9. Such tapered leads may help concentrate the wicking solder on the face of the flank and aid in optical inspection.

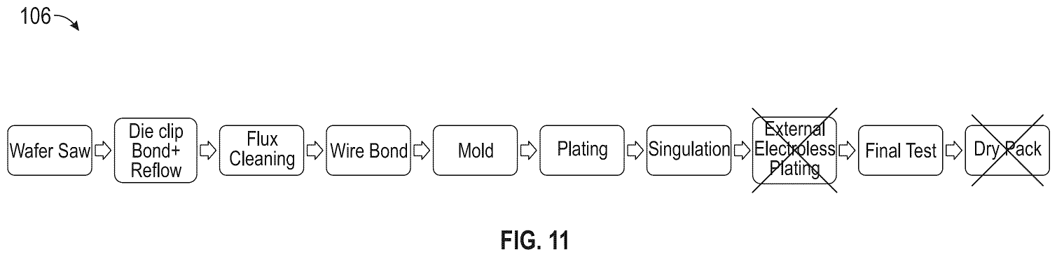

Referring to FIG. 11, a flow chart of an implementation of a method of forming a semiconductor package 106 is illustrated. As illustrated, the method begins with sawing and picking one or more semiconductor die from a semiconductor substrate. The semiconductor die is then bonded to a leadframe/substrate along with a clip followed by a reflow process to form bonds between the electrical connectors (here a clip), the leadframe/substrate, and the semiconductor die. A flux cleaning operation then is used to remove any flux used with a solder used for the clip and/or die bonding process. Electrical connectors (here wirebonds) are then formed during a wire bond operation to the semiconductor die and/or the clip and/or one or more leads of the leadframe. Electrically insulating material (here a mold compound) is then applied over the leadframe/substrate and other components leaving the ends of the leads exposed along with the tie bars. In this method implementation, an electroplating operation is then carried out that applies a solder wettable material over the exposed portions of the leads. A singulation operation is then used that cuts the leads and exposes the flanks thereof while freeing the semiconductor package from the leadframe.

In the method implementations disclosed herein, because of the presence of the through holes, a portion of the flanks of the resulting leads are already covered with the electroplated layer. Since the flanks are the portion being that part that is most helpful for optical inspection and the electroplated layer can be plated to a desired thickness in excess of 2 microns, there is no need for a separate electroless plating operation (which may be done at an external vendor) prior to final test or use of dry packing prior to shipping to customers. The ability to eliminate both of these processing steps may reduce cost, increase yields, and increase manufacturing throughput times.

Furthermore, while the use of dummy tie bars can be used to make electrical connections interior to a semiconductor package to allow for an electrical connection for electroplating of a flank, this operation has not been extended to situations where more than one semiconductor die is present in the semiconductor package. As a result, the present implementations enable wettable flanks at a desired thickness through electroplating in a multi-semiconductor package like those illustrated herein without the use of dummy tie bars.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. A substrate comprising:
a first side coupled with a first plurality of leads, the first side comprising a first set of spaced apart through holes therein; and
a second side coupled with a second plurality of leads, the second side comprising a second set of spaced apart through holes therein;
wherein the first side opposes the second side;
wherein a portion of a first set of edges of the first set of spaced apart through holes form a first set of wettable flanks for the first plurality of leads; and
wherein a portion of a second set of edges of the second set of spaced apart through holes form a second set of wettable flanks for the second plurality of leads.

2. The substrate of claim 1, further comprising a set of die flags.

3. The substrate of claim 1, further comprising a set of tie bars.

4. The substrate of claim 1, wherein the first set of wettable flanks and the second set of wettable flanks are configured to extend beyond a surface of an electrically insulating material when an electrically insulating material is coupled over the substrate.

5. A semiconductor package comprising:
a substrate comprising:
a first side coupled with a first plurality of leads, the first side comprising a first set of through holes therein; and
a second side coupled with a second plurality of leads, the second side comprising a second set of through holes therein;
one or more semiconductor die coupled to the substrate; and
an electrically insulating material coupled over the one or more semiconductor die and coupled to the substrate;
wherein a first set of edges of the first set of spaced apart through holes extend from the electrically insulating material; and
wherein a second set of edges of the second set of spaced apart through holes extend from the electrically insulating material.

6. The semiconductor package of claim 5, wherein the first set of edges form a first set of wettable flanks for the first plurality of leads.

7. The semiconductor package of claim 5, wherein the second set of edges form a second set of wettable flanks for the second plurality of leads.

8. The semiconductor package of claim 5, wherein remaining portions of the first side each comprise two reentrant openings forming a T-shape.

9. The semiconductor package of claim 5, wherein remaining portions of the second side each comprise two reentrant openings forming a T-shape.

10. The semiconductor package of claim 5, wherein each edge of the first set of edges comprises a straight line.

11. The semiconductor package of claim 5, wherein each edge of the second set of edges comprises a straight line.

12. The semiconductor package of claim 5, wherein an edge of the first set of edges comprises a reentrant angle.

13. The semiconductor package of claim 5, wherein an edge of the second set of edges comprises a reentrant angle.

14. The semiconductor package of claim 5, wherein an edge of the first set of edges comprises a reentrant opening.

15. The semiconductor package of claim 5, wherein an edge of the second set of edges comprises a reentrant opening.

16. The semiconductor package of claim 5, wherein flanks of the first plurality of leads and the second plurality of leads are straight cut.

17. The semiconductor package of claim 5, wherein flanks of the first plurality of leads and the second plurality of leads are flared.

18. The semiconductor package of claim 5, wherein flanks of the first plurality of leads and the second plurality of leads are tapered.

19. A method of forming a semiconductor package, the method comprising:
providing a substrate comprising:
a first side coupled with a first plurality of leads, the first side comprising a first set of through holes therein; and
a second side coupled with a second plurality of leads, the second side comprising a second set of through holes therein;
coupling one or more semiconductor die to the substrate;
applying an electrically insulating material over the one or more semiconductor die and to the substrate;
cutting the first plurality of leads at each through hole of the first set of through holes; and
cutting the second plurality of leads at each through hole of the second set of through holes.

20. The method of claim 19, further comprising preventing electrically insulating material bleed using two reentrant openings in each lead of the first plurality of leads and two reentrant openings in each lead of the second plurality of leads.
